(19) United States
(12) Patent Application Publication
(10) Pub. No.: US 2008/0094788 A1
(43) Pub. Date: Apr. 24, 2008

(54) Memory card having display function using piezoelectric effect and method thereof

(76) Inventor: Kwang-Chol Choe, Seoul (KR)

Correspondence Address: LAW OFFICE OF MONICA H CHOI, P O BOX 3424, DUBLIN, OH, 430160204, US

(21) Appl. No.: 11/810,541

(22) Filed: Jun. 6, 2007

(30) Foreign Application Priority Data
Oct. 23, 2006 (KR) 2006-103007

(51) Int. Cl. H05K 5/00

(52) U.S. Cl. 361/681

(57) ABSTRACT

A memory card includes a piezoelectric material and a display unit. The piezoelectric material generates a voltage from external pressure applied thereon, and the display unit displays information using the generated voltage. Thus, information is displayed on the memory card at the discretion of the user pressing the piezoelectric material without using any additional equipment. Also, few components are added to the memory card for such a display function such that the small form of the memory card is retained.

### BACKGROUND OF THE INVENTION

This application claims priority under 35 USC § 119 to Korean Patent Application No. 2006-103007, filed on Oct. 23, 2006 in the Korean Intellectual Property Office, the disclosure of which is incorporated herein in its entirety by reference.

1. Field of the Invention

The present invention relates generally to memory cards, and more particularly, to a memory card having a display function powered by energy generated using piezoelectric effect.

2. Background of the Invention

With portable electronic devices, demand for memory devices has been rapidly increasing. Non-volatile memory such as flash EEPROM, which is neither a conventional hard disk nor a hard disk drive type, has been widely used as the main data storage device. The non-volatile memory is mainly used in a memory card such as a smart card, which is attached to or detached from an electronic device.

The memory card includes non-volatile memory of a NAND type or a NOR type for storing data, a memory controller for controlling the operation of the non-volatile memory, and an interface including an input/output interface. The memory card is connected to a portable electronic device or a PC via the input/output interface. The memory card has a standardized form for flexible use among many types of electronic devices.

Also, after being disconnected from a portable electronic device and connected to a PC, the memory card exchanges information with the PC in an upload/download form. In addition, when a fixed memory capacity of the memory card is fully used, the memory card erases unnecessary information therein or downloads information to another device such as a PC or a portable electronic device, for attaining more available capacity.

For determining available memory capacity in a memory card, the memory card is required to be connected to a PC or a portable electronic device with an established operation for determining such available memory capacity, in the prior art. In the prior art, if a PC or a portable electronic device is unavailable or out of order or out of power, determining the remaining usable capacity of the memory card is not possible.

To solve such an inconvenience, the prior art proposes an apparatus having a memory card connected thereto for checking the remaining memory capacity of the memory card. Alternatively, the remaining memory capacity of the memory card is proposed to be displayed on the memory card before the power of an electronic device having the memory card connected thereto is shut off, and thereafter.

However, in the former case, additional equipment is still required to determine the remaining memory capacity. In the latter case, the remaining memory capacity is unconditionally displayed not through any choice of the user. Therefore, such prior art mechanisms may be unattractive to a user desiring to know the remaining memory capacity when required. Also, such prior art mechanisms inefficiently use additional equipment.

### SUMMARY OF THE INVENTION

Accordingly, the present invention uses a piezoelectric material for generating energy upon application of pressure by a user for displaying information on a memory card.

A memory card according to an embodiment of the present invention includes a piezoelectric material and a display unit. The piezoelectric material generates a voltage from external pressure applied thereon, and the display unit displays information using the generated voltage.

In another embodiment of the present invention, the memory card further includes a mode selection unit set by a user for specifying a type of the information to be displayed on the display unit. Such displayed information is at least one of remaining memory capacity, used memory capacity, user information, user identification number, and device identification number.

In a further embodiment of the present invention, the memory card also includes a capacitor for storing charge generated from the piezoelectric material. In that case, the display unit displays the information when the voltage at the capacitor reaches a threshold voltage.

In another embodiment of the present invention, the memory card includes a display controller for turning off the display unit after a predetermined time period of displaying the information. In that case, the capacitor retains un-used charge after the predetermined time period.

In a further embodiment of the present invention, the memory card includes a main memory device and an additional memory device separate from the main memory device with the additional memory device storing the information to be displayed.

In one example of the present invention, the additional memory device is part of the display unit. Alternatively, the additional memory device is separate from the display unit.

In another embodiment of the present invention, the main memory device of the memory card stores the information to be displayed.

In a further embodiment of the present invention, the memory card includes at least one switch unit for automatically attaching/detaching the display unit from a memory controller of the memory card when the memory card is attached/detached from an external device.

In this manner, information regarding the memory card is displayed on the memory card at the discretion of the user without using any additional equipment.

### BRIEF DESCRIPTION OF THE DRAWINGS

The above and other features and advantages of the present invention will become more apparent when described in detailed exemplary embodiments thereof with reference to the attached drawings in which:

FIG. 1 shows a plan view of a piezoelectric material for generating a voltage to be used in a memory card, according to an embodiment of the present invention;

FIG. 2 shows a flowchart of steps during operation of a memory card that displays information, according to an embodiment of the present invention;

FIGS. 3A, 3B, 3C, and 3D show plan views of memory cards with example locations of a display unit and a piezoelectric material, according to embodiments of the present invention;

FIGS. 4A, 4B, and 4C show plan views with example display units for displaying used memory capacity, according to embodiments of the present invention;

FIGS. 5A, 5B, and 5C show plan views with example display units for displaying remaining memory capacity, according to embodiments of the present invention;

FIG. 6 shows a block diagram of a memory card with an additional memory device that is part of a display unit and that is for storing information to be displayed, according to an embodiment of the present invention;

FIG. 7 shows a block diagram of a memory card that stores information to be displayed in a main memory device, according to another embodiment of the present invention; and

FIG. 8 shows a block diagram of a memory card with an additional memory device that is separate from a display unit and that is for storing information to be displayed, according to another embodiment of the present invention.

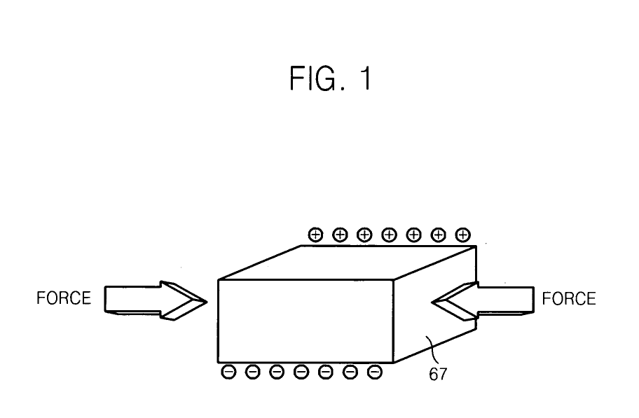

The figures referred to herein are drawn for clarity of illustration and are not necessarily drawn to scale. Elements having the same reference number in FIGS. 1, 2, 3A, 3B, 3C, 3D, 4A, 4B, 4C, 5A, 5B, 5C, 6, 7, and 8 refer to elements having similar structure and/or function.

### DETAILED DESCRIPTION OF THE INVENTION

FIG. 1 shows a plan view of a piezoelectric material 67 used in a memory card that displays information according to an embodiment of the present invention. When force or pressure is applied on the piezoelectric material 67, mechanical stress is created through the piezoelectric material 67 that accordingly generates a voltage thereon.

On the other hand, if a voltage is applied across the piezoelectric material 67, the piezoelectric material 67 contracts or expands according to a direction of the positive pole. Such characteristics of the piezoelectric material 67 is referred to as the “Piezo Effect” that transforms mechanical change to electrical change, and conversely that transforms electrical change to mechanical change. Examples of such a piezoelectric material 67 include crystals such as Crystal, Rochelle Salt, or Barium Titanate. Piezoelectric materials in general and individually are known to one of ordinary skill in the art.

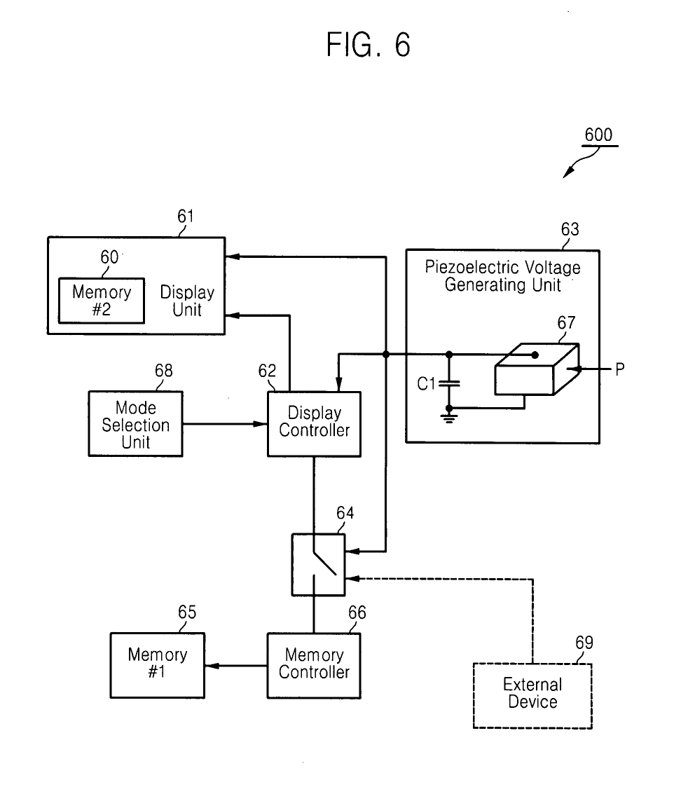

FIG. 6 shows a block diagram of a memory card 600 that displays information according to an embodiment of the present invention. The memory card 600 may be a secure digital (SD) card, a multi-media card MMC, a memory stick, a compactflash™, a sD-picture card, or a smartmedia™ that is used in various electronic devices such as digital cameras, portable game devices, camcorders, mobile telephones, televisions, or even printers,

Referring to FIG. 6, the memory card 600 includes a main memory device 65 and a memory controller 66 for controlling operation of the main memory device 65. The main memory device 65 may be a flash EEPROM and is for the typical memory functions associate with a memory card. The memory card 600 also includes a display unit 61 with an additional memory device 60 that stores information to be displayed on the display unit 61. The memory card 600 further includes a display controller 62 for controlling operation of the display unit 61 and a mode selection unit 68 to be set by a user.

The user sets a mode in the mode selection unit 68 such as by switches or by programming a code therein for specifying the type of information to be displayed by the display unit 61. For example, such information displayed by the display unit 61 includes at least one of remaining memory capacity and/or used memory capacity of the main memory device 65, user information, a user identification number, and a device identification number.

Additionally in FIG. 6, the memory card 600 includes a piezoelectric voltage generating unit 63 for generating energy used by components 61, 62, and 64 in FIG. 6 for displaying information on the display unit 61. The piezoelectric voltage generating unit 63 includes the piezoelectric material 67 and a capacitor C1 coupled across the piezoelectric material 67. The present invention may be practiced with or without the capacitor C1.

In addition, the memory card 600 includes a switch unit 64 coupled between the display controller 62 and the memory controller 66. The present invention may be practiced with or without the switch unit 64.

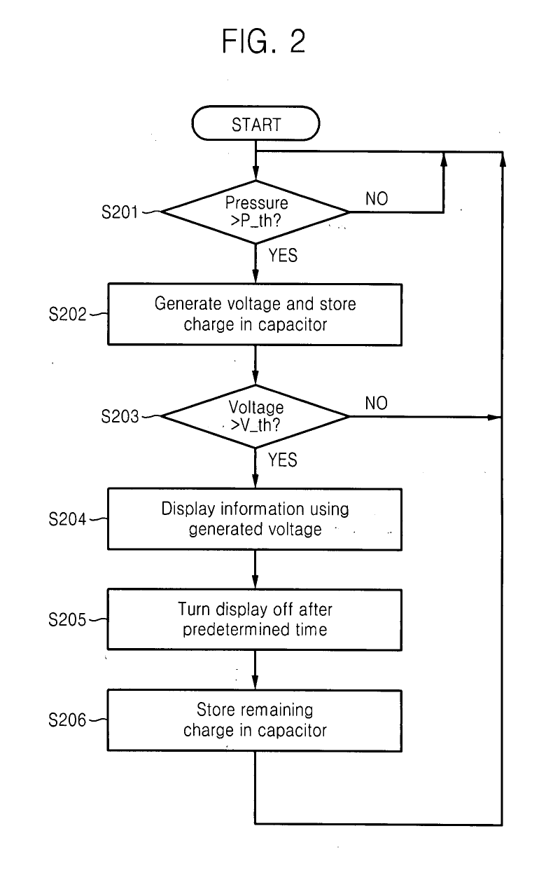

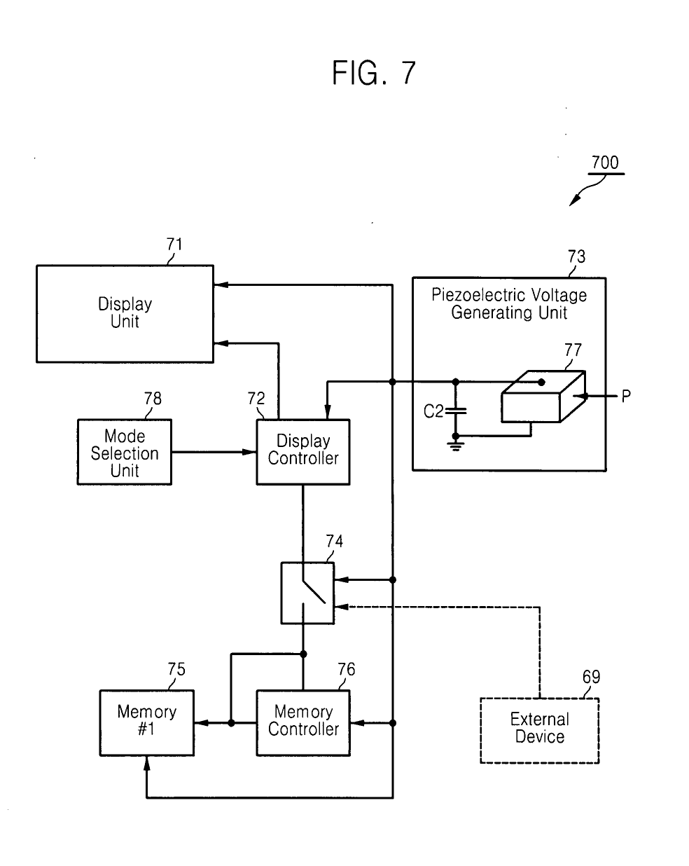

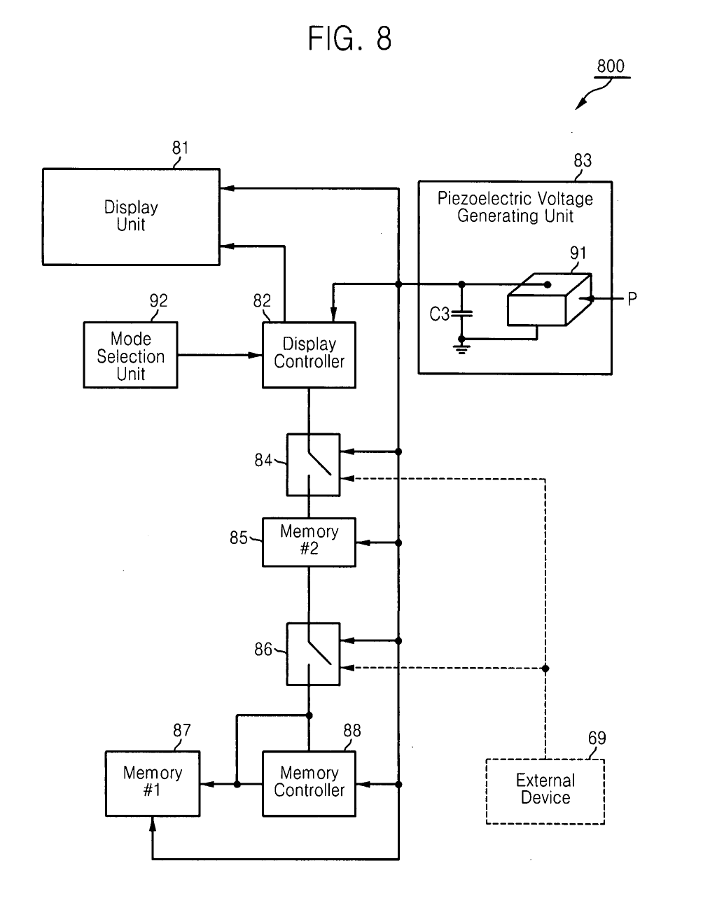

FIG. 2 shows a flowchart of steps during operation of the memory card 600 of FIG. 6 (and a memory card 700 and 800 of FIGS. 7 and 8) for displaying information thereon. Operation of the memory card 600 of FIG. 6 is now described.

Referring to FIGS. 2 and 6, when a user desires to confirm information regarding the memory card 600 such as the remaining capacity of the main memory device 65, the user presses the piezoelectric material 67. A voltage is generated across the piezoelectric material 67 when the applied pressure across the piezoelectric material 67 is greater than a threshold pressure P_th (steps S201 and S202 of FIG. 2).

Otherwise if the applied pressure is not greater than the threshold pressure P_th, the piezoelectric material 67 just remains without a voltage generated thereon until a sufficient pressure is applied (step S201 of FIG. 2). Such a pressure threshold P_th ensures that the display unit 61 is not operated if slight pressure is applied on the piezoelectric material 67 without any intended display of information such as when the memory card 600 is put into a pocket.

Additionally, such a pressure threshold P_th may allow for display of different kinds of information. For example, predetermined types of information such as a user's telephone number or customer number may be displayed for adequate pressure applied on the memory card 600 in case the memory card is lost. Different types of information may be displayed on the display unit 61 according to the degree of applied pressure.

When the applied pressure is greater than the threshold pressure P_th, the voltage generated across the piezoelectric material 67 is applied on the capacitor C1 that stores charge thereon from such generated voltage. If the generated voltage across the capacitor C1 and the piezoelectric material 67 is greater than a threshold voltage V_th (step S203 of FIG. 2), information regarding the memory card is displayed on the display unit 61 (step S204 of FIG. 2). The capacitor C1 still stores charge generated across the piezoelectric material 67 even if the voltage generated across the piezoelectric material 67 is not greater than the threshold voltage V_th.

In the case that the generated voltage at the capacitor C1 is greater than the threshold voltage V_th, the voltage generated at the capacitor C1 is applied for powering the display unit 61, the display controller 62, and the switch unit 64. Upon power-up when such applied voltage is greater than the threshold voltage V_th, the display controller 62 controls the display unit 61 to display information regarding the memory card 600 (step S204 of FIG. 2).

In one embodiment of the present invention, the display controller 62 controls the display unit 61 to display the type of information as specified in the mode selection unit 68. Such information type as specified by the user includes at least one of remaining memory capacity and/or used memory capacity of the main memory device 65, user information such as user contact information, a user identification number, and a device identification number.

The mode selection unit 68 may include switches disposed on a surface of the memory card 600 such that the user may set such switches for specifying the type of information to be displayed. The information to be displayed is stored in the additional memory device 60 included as part of the display unit 61 in the embodiment of FIG. 6. The additional memory device 60 is implemented as a flash EEPROM in one embodiment of the present invention.

The display controller 62 controls the display unit 61 to display such specified information for a predetermined time period, and thereafter turns off the display unit 61 (step S205 of FIG. 2) for conserving power. Alternatively, the display controller 62 controls the display unit 61 to display such specified information until the generated voltage at the capacitor C1 becomes less than the threshold voltage V_th.

The display unit 61 includes a flat panel display device such as a TFT-LCD (thin film transistor liquid crystal display), a PDP (plasma display panel), or an OLED (organic light emitting diode) display in one embodiment of the present invention. In that case, the display unit 61 visually displays the information as specified by the mode selection unit 68 and as stored in the additional memory device 60. Alternatively, the display unit 61 includes a phonetic device such as a speaker such that the display unit 61 aurally communicates the information as specified by the mode selection unit 68 and as stored in the additional memory device 60.

After the predetermined time period of displaying the information on the display unit 61, the capacitor C1 stores any charge remaining after the display of the information (step S206 of FIG. 2). Thereafter, the flowchart of FIG. 2 returns to step S201 to monitor for any subsequent pressure applied by the user on the piezoelectric material 67.

The capacitor C1 may also generate additional charge stored therein in response to received light for boosting the voltage generated thereon. Such a capacitor is advantageous in the case that the voltage generated from pressure applied on the piezoelectric material 67 alone is insufficient for driving the display unit 61 and the display controller 62.

Further referring to FIG. 6, the memory card 600 includes the switch unit 64 for controlling connection between the display controller 62 and the memory controller 66. The switch unit 64 is controlled by the voltage generated at the capacitor C1 in one embodiment of the present invention. The switch unit 64 may also be controlled by voltage from an external device 69 when the memory card 600 is connected to the external device 69.

For example, the switch unit 64 is automatically opened to separate the display unit 62 from the memory controller 66 when the memory card 600 is attached to the external device 69 such that the memory card 600 performs normal memory card operations. Therefore, the display function by the components 61 and 62 becomes disconnected from the external device 69 during such normal operation for avoiding disadvantages of such a display function such as unnecessary power consumption.

Alternatively, the switch unit 64 may be automatically opened when the memory card 600 is separated from the external device 69 after having been automatically closed when the memory card 600 was attached to the external device 69. In that case, the display unit 61 and the display controller 62 use a voltage generated from the attached external device 69 for providing the display function and do not require the voltage generated by the piezoelectric voltage generating unit 63.

Further in that case, with the switch unit 64 being closed when the memory card 600 is attached to the external device 69, the user may program the information to be displayed into the additional memory device 60 via the external device 69 which may be a PC or a portable electronic device. In that case, the display controller 62 stores such specified information into a predetermined location of the additional memory device 60.

In that case, the additional memory device 60 may include predetermined locations each for storing specific information such as user telephone number, user identification number, card identification number, remaining memory capacity, etc. For example, the user telephone number may be used to track the owner of the memory card 600 when the memory card 600 is lost. When a finder of the memory card 600 sets switches of the mode selection unit 68 to a user information mode and presses the piezoelectric material 67, the display unit 61 displays the telephone number of the original owner of the memory card 600.

Alternatively, the switch unit 64 may remain closed without being switched when the memory card 600 is attached to or detached from the external device 69, but may be automatically opened when a user presses the piezoelectric material 67 with sufficient voltage generated thereon. In that case, during normal operation of the memory card 600 when the user would not press the piezoelectric material 67, the memory controller 66 or the external device 69 may control the display unit 61 via the display controller 62.

In the embodiment of FIG. 6, the additional memory device 60 for storing the information to be displayed on the display unit 61 is formed as part of the display unit 61 such that relatively low power is consumed.

FIG. 7 shows a block diagram of a memory card 700 according to an alternative embodiment of the present invention. Referring to FIG. 7, the memory card 700 includes a display unit 71, a display controller 72, a piezoelectric voltage generating unit 73 having a piezoelectric material 77 and a capacitor C2, a mode selection unit 78, a main memory device 75, a memory controller 76, and a switch unit 74. Such components of FIG. 7 operate similarly to the like-named components of FIG. 6 for displaying information regarding the memory card 700 according to the flowchart of FIG. 2.

However in FIG. 7, the information to be displayed on the display unit 71 is stored in the main memory device 75 such that an additional memory device is not used. Thus in FIG. 7, the main memory device 75 and the memory controller 76 are also powered by the voltage generated at the capacitor C2 by the piezoelectric material 77 upon being pressed when the information stored in the main memory device 75 is retrieved through the memory controller 76. Such an embodiment of FIG. 7 may consume more power but use of the capacitor C2 helps to meet the power requirement.

Alternatively in the embodiment of FIG. 7, the information stored in the main memory device 75 may be retrieved directly from the main memory device 75 by the display controller 72. In that case, the display controller 72 is coupled through the switch unit 74 to the main memory device 75 thereby bypassing the memory controller 76. In such an embodiment, the memory controller 76 would not be powered by the piezoelectric voltage generating unit 73 thereby conserving power.

The switch unit 74 in FIG. 7 may be controlled by the voltage generated at the capacitor C2. The switch unit 74 may also be controlled by a voltage generated by the external device 69 that the memory card 700 attaches to. In that case, the switch 74 is opened for separating the display unit 71 from the memory controller 76 when the memory card 700 is attached to the external device 69 for performing normal memory card operations. Therefore, the display function by the components 71 and 72 becomes disconnected from the external device 69 during such normal operation for avoiding disadvantages of such a display function such as unnecessary power consumption.

Alternatively, the switch unit 74 may be automatically opened when the memory card 700 is separated from the external device 69 after having been automatically closed when the memory card 700 was attached to the external device 69. In that case, the display unit 71 and the display controller 72 uses a voltage generated from the attached external device 69 for providing the display function and does not require the voltage generated by the piezoelectric voltage generating unit 73.

Further in that case, when the memory card 700 is attached to the external device 69, the user may program the information to be displayed into the main memory device 75 via the external device 69 which may be a PC or a portable electronic device. In that case, the memory controller 76 stores such specified information into a predetermined location of the main memory device 75.

Also in that case, the main memory device 75 may include predetermined locations each for storing specific information such as user telephone number, user identification number, card identification number, remaining memory capacity, etc. Each of such information may be displayed on the displayed unit 71 upon specification by the user in the mode selection unit 78.

Alternatively, the switch unit 74 may remain opened without being switched when the memory card 700 is attached to or detached from the external device 69, but may be automatically closed when a user presses the piezoelectric material 77 with sufficient voltage generated thereon. In that case, the display unit 71 may display information stored in the main memory device 75 when the user presses the piezoelectric material 77 with sufficient voltage generated at the capacitor C2.

FIG. 8 shows a block diagram of a memory card 800 according to another embodiment of the present invention. Referring to FIG. 8, the memory card 800 includes an additional memory device 85 separate from a main memory device 87, and the additional memory device 85 stores information to be displayed on the display unit 81. The memory card 800 also includes a display controller 82, a piezoelectric voltage generating unit 83 with a piezoelectric material 91 and a capacitor C3, a mode selection unit 92, and a memory controller 88. Such components of FIG. 8 operate similarly to the like-named components of FIG. 6 for displaying information regarding the memory card 800 according to the flowchart of FIG. 2.

However in FIG. 8, the additional memory device 85 for storing information to be displayed is separate from the display unit 81. Thus, the additional memory device 85 may be controlled by the display controller 82 or the main memory controller 88.

The memory card 800 also includes a first switch unit 84 and a second switch unit 86. The first switch unit 84 switches connection between the display controller 82 and the additional memory device 85. The second switch unit 86 switches connection between the additional memory device 85 and the memory controller 88. The voltage at the capacitor C3 powers the display unit 81, the display controller 82, the first and second switch units 84 and 86, the additional memory device 85, and the memory controller 88 when needed.

The second switch unit 86 is opened for separating the additional memory device 85 from the memory controller 88 when the memory card 800 is attached to the external device 69 for performing normal memory card operations. Therefore, the display function by the components 81 and 82 becomes disconnected from the external device 69 during such normal operation for avoiding disadvantages of such a display function such as unnecessary power consumption.

Also, during such normal operations, the memory controller 88 stores information into the additional memory device 85 through the second switch unit 86 that is closed. The first switch unit 84 is opened during such an operation for separating the additional memory device 85 from the display controller 82. Thus, the first and second switching units 84 and 86 may be controlled to be closed and opened separately. Alternatively, the first and second switching units 84 and 86 may be controlled to be closed and opened together.

Furthermore, the second switch unit 86 may be automatically opened when the memory card 800 is detached from the external device 69, and automatically closed when the memory card 800 is attached to the external device 69. In that case, the first switch unit 84 may be kept closed at all times or may be switched similarly as the second switch unit 86. Thus, the display unit 81 and the display controller 82 use a voltage generated from the attached external device 69 for providing the display function and do not require the voltage generated by the piezoelectric voltage generating unit 83.

Further in that case, with the second switch unit 86 being closed when the memory card 800 is attached to the external device 69, the user may program the information to be displayed into the additional memory device 85 via the external device 69 which may be a PC or a portable electronic device. In that case, the memory controller 88 stores such specified information into a predetermined location of the additional memory device 85.

Alternatively, the first switch unit 84 and the second switch unit 86 remains closed without being switched when the memory card 800 is attached to the external device 69, but the second switch 86 is opened automatically when a user presses the piezoelectric material 91 with a sufficient voltage generated at the capacitor C3. In that case, during a normal operation of the memory card 800 when the user would not press the piezoelectric material 91, the memory controller 88 or the external device 69 may control the display unit 81 via the display controller 82.

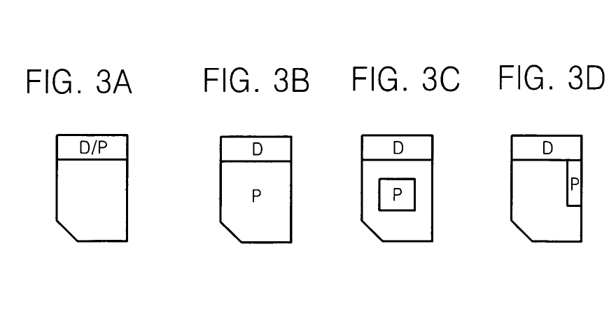

FIGS. 3A, 3B, 3C, and 3D show plan views of example memory cards with a display unit D and a piezoelectric material P disposed thereon. The display unit D is any of the display units 61, 71, and 81 of FIGS. 6, 7, and 8, and the piezoelectric material P is any of the piezoelectric materials 67, 77, and 91 of FIGS. 6, 7, and 8. In FIGS. 3A, 3B, 3C, and 3D, a display window of the display unit D is located toward a top of the memory cards. However, the present invention may also be practiced with such a display window being located anywhere on the memory card.

FIG. 3A shows the display window D and the piezoelectric material P located in a same place at the top section of the memory card. When a crystal is used for the piezoelectric material, the transparent nature of the crystal allows the crystal to be used also for the display window D. In that case, a user would press the display window D for displaying information about the memory card thereon.

FIG. 3B shows the display window D located at the top section of the memory card and the piezoelectric material P located in the remaining part of the memory card. FIG. 3C shows the display window D located at the top section of the memory card and the piezoelectric material P located only in a middle portion of the memory card. FIG. 3D shows the display window D located at the top section of the memory card and the piezoelectric material P located in a left or right portion of the memory card.

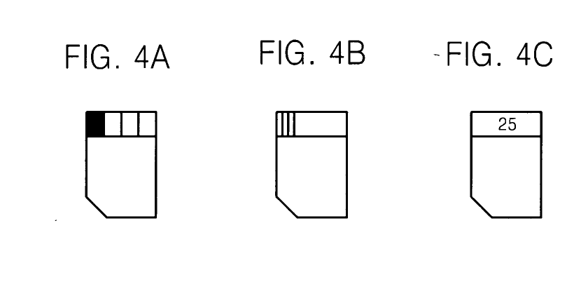

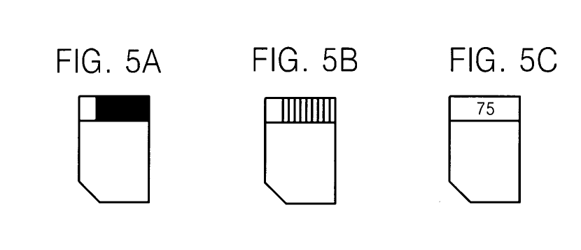

FIGS. 4A, 4B, and 4C show plan views of example information displayed on the display window of the memory card. FIG. 4A displays used memory capacity in a continuous bar graph form, and FIG. 4B displays used memory capacity in a discrete bar graph form. FIG. 4C displays used memory capacity in numeric form. The form for display may be specified by the user through the mode selection unit 68, 78, or 92. FIGS. 5A, 5B, and 5C show the display of the remaining memory capacity corresponding to the used memory capacity in similar forms of FIGS. 4A, 4B, and 4C, respectively.

In this manner, information regarding a memory card is displayed on the memory card at the discretion of the user pressing the piezoelectric material without using any additional equipment. In addition, few components are added to the memory card for retaining the small form of the memory card.

While the present invention has been particularly shown and described with reference to exemplary embodiments thereof, it will be understood by those of ordinary skill in the art that various changes in form and details may be made therein without departing from the spirit and scope of the present invention as defined by the following claims.

The present invention is limited only as defined in the following claims and equivalents thereof.

What is claimed is:

1. A method of displaying information of a memory card, comprising:
generating a voltage from external pressure applied on a piezoelectric material formed as part of the memory card; and
displaying information on a display unit disposed on the memory card using the generated voltage.

2. The method of claim 1, further comprising:
selecting information to be displayed according to a mode selection specified by a user.

3. The method of claim 1, further comprising:
storing charge generated from the piezoelectric material in a capacitor; and
displaying the information on the display unit when the voltage at the capacitor reaches a threshold voltage.

4. The method of claim 1, wherein the information displayed is at least one of remaining memory capacity, used memory capacity, user information, user identification number, and device identification number.

5. The method of claim 1, further comprising:
turning off the display unit after a predetermined time period of displaying the information.

6. The method of claim 5, further comprising:
generating the voltage at a capacitor that stores charge generated from the piezoelectric material, and wherein the capacitor retains un-used charge after the predetermined time period.

7. The method of claim 1, further comprising:
storing the information to be displayed in an additional memory device that is separate from a main memory device of the memory card.

8. The method of claim 7, wherein the additional memory device is part of the display unit.

9. The method of claim 7, wherein the additional memory device is separate from the display unit.

10. The method of claim 1, further comprising:
storing the information to be displayed in a main memory device of the memory card.

11. The method of claim 1, further comprising:
automatically attaching/detaching the display unit from a memory controller of the memory card when the memory card is attached/detached from an external device.

12. A memory card comprising:
a piezoelectric material that generates a voltage from external pressure applied thereon; and
a display unit for displaying information using the generated voltage.

13. The memory card of claim 12, further comprising:
a mode selection unit set by a user for specifying a type of the information to be displayed on the display unit.

14. The memory card of claim 12, further comprising:
a capacitor for storing charge generated from the piezoelectric material, wherein the display unit displays the information when the voltage at the capacitor reaches a threshold voltage.

15. The memory card of claim 12, wherein the information displayed is at least one of remaining memory capacity, used memory capacity, user information, user identification number, and device identification number.

16. The memory card of claim 12, further comprising:
a display controller for turning off the display unit after a predetermined time period of displaying the information.

17. The memory card of claim 16, further comprising:
a capacitor for storing charge generated from the piezoelectric material, wherein the display unit displays the information using the voltage at the capacitor, and wherein the capacitor retains un-used charge after the predetermined time period.

18. The memory card of claim 12, further comprising:
a main memory device; and
an additional memory device separate from the main memory device, wherein the additional memory device stores the information to be displayed.

19. The memory card of claim 18, wherein the additional memory device is part of the display unit.

20. The memory card of claim 18, wherein the additional memory device is separate from the display unit.

21. The memory card of claim 12, further comprising:
a main memory device that stores the information to be displayed.

22. The memory card of claim 12, further comprising:
at least one switch unit for automatically attaching/detaching the display unit from a memory controller of the memory card when the memory card is attached/detached from an external device.
